(19) United States
(12) Patent Application Publication
(10) Pub. No.: US 2014/0203819 A1
(43) Pub. Date: Jul. 24, 2014

(54) Cloaked electromagnetic field sensor

(71) Applicants: Walter D. Sessions, King George, VA (US); Kevin A. Boulais, La Plata, MD (US); Jennifer K. Roames, Fredericksburg, VA (US)

(72) Inventors: Walter D. Sessions, King George, VA (US); Kevin A. Boulais, La Plata, MD (US); Jennifer K. Roames, Fredericksburg, VA (US)

(73) Assignee: United States Government, as represented by the Secretary of the Navy, Arlington, VA (US)

(21) Appl. No.: 13/199,960

(22) Filed: Aug. 24, 2011

(51) Int. Cl. G01R 29/00

(52) U.S. Cl. 324/609

(57) ABSTRACT

A cloaked field sensor apparatus and system using a cloaking barrier sheath to substantially enclose the surface of a transmitter conduit exposed to an electromagnetic field being measured to reduce the field sensor's interference with the electromagnetic field being measured. Multiple cloaked field sensor apparatuses may be aligned in an array and use identical or different cloaking barrier sheaths.

### STATEMENT OF GOVERNMENT INTEREST

The invention described herein was made in the performance of official duties by one or more employees of the Department of the Navy, and the invention herein may be manufactured, practiced, used, and/or licensed by or for the Government of the United States of America without the payment of any royalties thereon or therefor.

### FIELD OF THE INVENTION

The present invention relates to the field of electromagnetic testing and more specifically to an apparatus and system to more accurately measure the actual strength of electric or magnetic fields without altering the field being measured.

### BRIEF DESCRIPTION OF THE DRAWINGS

FIG. 1 illustrates an exemplary embodiment of a cloaked field sensor apparatus.

FIG. 2 illustrates an exemplary embodiment of a cloaked field sensor apparatus in conjunction with an electromagnetic source that emits an electromagnetic field.

FIG. 3 illustrates an exemplary embodiment of multiple cloaked field sensor apparatuses arranged to form a field sensor array in an electromagnetic field emitted by an electromagnetic source.

### TERMS OF ART, AS USED WITHIN

The term “cloak” or “cloaking” means to reduce the signature of an object in an electromagnetic field. A cloak may refer to a structural component or apparatus that accomplishes cloaking.

The term “cloaking barrier sheath” means any barrier applied to the transmitter component of a field sensor that cloaks the component by reducing the signature of said transmitter component. A cloaking barrier sheath may surround or enclose a transmitter component in a manner analogous to the way colored insulation surrounds or encloses an electric wire.

The term “electromagnetic cloaking interface” refers to the measurable area where a cloaking barrier sheath interacts with an electromagnetic field to reduce the signature of a transmitter component.

The term “field sensor” means a device designed to measure the strength of an electromagnetic field.

The term “mantle cloak” means a material, which may be comprised of a metamaterial, that has a patterned metallic surface engineered or otherwise modified to reduce the signature of an object.

The term “metal lens” means a reflective material capable of producing desired wave propagation.

The term “metamaterial cloak” refers to a synthetic material or composite material that is structurally altered to control its electromagnetic signature or other properties, including but not limited to, its refractive index. A metamaterial may be specifically engineered with intended desirable qualities to satisfy a design need.

The term “plasmonic material” refers to a composite material that is engineered to achieve desired electromagnetic properties having low positive dielectric permittivity. A plasmonic material may be comprised of metamaterials or metasurfaces.

The term “scattering-reduction material” is a material engineering to reduce scattering, which is the deviation from a straight trajectory caused by the interaction of an electromagnetic field and an object in said electromagnetic field. This can be, for example, in amplitude, in phase or both.

The term “signature” means the quantifiable alteration of an electromagnetic field by any object or phenomena capable of affecting an electromagnetic field.

The term “transmitter conduit” means an attachment that communicates with a field sensor so that it transmits the output of the field sensor to a remotely located receiver configured to receive such output. A transmitter conduit may include, but is not limited to, an electric wire or cable, a fiber optic cable, or any other material or device capable of transmitting the output of a field sensor.

### BACKGROUND

Devices and systems for measuring an electromagnetic (EM) field have known limitations. In particular, the measuring tools can change or alter the EM field. For example, the field sensors, cables, and electronic devices used to take the measurements can cause distortions in the EM field being measured. These changes can affect the accuracy of the measurements and even interfere with the proper functioning of the device generating the EM field.

One method known in the art to reduce interference with the EM field is the use of fiber optic links. This method requires a dedicated electronic device to convert the signal from the field sensor to the appropriate optical wavelength for the fiber optic link. The electronic device may be reduced in size in order to minimize its signature, and may include a battery to prevent external power wires from interfering with the electromagnetic wave.

Another method known in the art is the use of out-of-band radio frequency (RF) to reduce interference with the field being measured. This method also requires use of a dedicated electronic device that may be reduced in size to minimize its signature. However, functional and manufacturing constraints place limitations on how small the electronic devices used with fiber optic links and out-of-band RF may be made, and the reduction in interference using these methods is therefore limited.

A third method known in the art to reduce field disruption involves the placement of the RF cables, such as can be oriented perpendicular to the field polarization. This method can only be used when the polarization of the electromagnetic field being measured is linear (either horizontal, vertical or a combination thereof). No method or apparatus known in the art significantly reduces the signature of the field sensor and the transmitter conduit operatively connected to it.

### SUMMARY OF THE INVENTION

Various exemplary embodiments provide a cloaked field sensor apparatus to reduce the signature of a field sensor for minimizing the effect of the cable on the electromagnetic field being measured. A transmitter component operatively coupled with a field sensor is substantially surrounded by a cloaking barrier sheath. Multiple cloaked electromagnetic field sensors may be aligned to create a sensor array. In a various embodiments, the cloaked field sensor may be passive. In other embodiments the cloak filed sensor may be low-loss, or alternatively active.

### DETAILED DESCRIPTION OF INVENTION

For the purpose of promoting an understanding of the present invention, references are made in the text to exemplary embodiments of a cloaked field sensor apparatus and a method to cloak aspects of a field sensor, only some of which are described herein. It should be understood that no limitations on the scope of the invention are intended by describing these exemplary embodiments. One of ordinary skill in the art will readily appreciate that alternate but functionally equivalent materials, components, and placement may be used. The inclusion of additional elements may be deemed readily apparent and obvious to an artisan of ordinary skill. Specific elements disclosed herein are not to be interpreted as limiting, but rather as a basis for the claims and as a representative basis for teaching one of ordinary skill in the art to employ the present invention.

It should be understood that the drawings are not necessarily to scale; instead emphasis has been placed upon illustrating the principles of the invention. In addition, in the embodiments depicted herein, like reference numerals in the various drawings, refer to identical or near identical structural elements. Moreover, the terms “substantially” or “approximately” as used herein may be applied to modify any quantitative representation that could permissibly vary without resulting in a change in the basic function to which it is related.

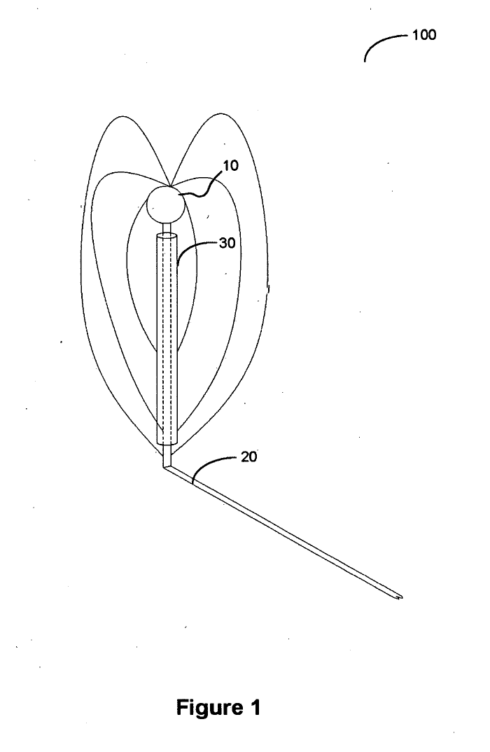

FIG. 1 illustrates an exemplary embodiment of a cloaked electromagnetic (EM) field sensor apparatus 100 that has a substantially reduced signature. This field sensor apparatus 100 minimizes disturbances to an EM field being measured thereby. In the exemplary embodiment shown, the cloaked field sensor apparatus 100 includes field sensor 10 (e.g., an antenna probe) and transmitter component 20, which transmits the output of field sensor 10 to a remotely-located receiver where its output can be read and interpreted. As illustrated, transmitter conduit 20 is an electric cable component. In further exemplary embodiments, transmitter conduit 20 may be any material capable of transmitting the output from field sensor 10, including, but not limited to, an electric wire or a waveguide (e.g., a fiber optic cable).

In the exemplary embodiment shown in FIG. 1, the cloaking barrier surface 30 completely surrounds the transmitter conduit 20 along the portion of its length that comes in contact with the EM field. By contrast, the field sensor 10 remains exposed to the EM field. This arrangement differs from concealed sensors, as described by A. Alù in “Cloaking a Sensor”, Phys. Rev. Left. 102 233901 (2009) that exhibit weak sensitivity. In the exemplary embodiment shown, a cloaking barrier sheath 30 is illustrated as a structural component that wraps around the transmitter conduit 20. Alternatively, the cloaking barrier surface 30 may be the outer layer of the transmitter conduit 20. In still further exemplary embodiments, the transmitter conduit 20 may be only substantially enclosed by the cloaking barrier sheath 30.

The cloaking barrier sheath 30 may be comprised of a mantle, metamaterial, plasmonic material, scattering-reduction material, or a metal lens. Cloaking barrier sheath 30 may also have a metallic surface with a periodic pattern that is smaller than the wavelength of the ambient EM field, such as metamaterial or metasurface cloaking. A period pattern causes EM waves to bend around cloaked field sensor apparatus 100 and reduces EM scattering. Plasmonic materials used as cloaking barrier sheath 30 may have low negative or low positive dielectric permittivity in order to reduce phase distortion.

In order to cloak an object, radiation must go around the object and reconstruct on the other side in both phase and amplitude. The path around an object embedded in free space, for example, is typically longer than the path radiation would take in free space away from the object. Free space radiation travels at the speed of light, and so the phase velocity of the wave taking the longer path must travel faster than the speed of light so the phase can reconstruct on the other side. This phase velocity can travel faster than light without violating relativistic laws as there is no energy moved thereby. Phase velocity υₚ in a material can be related to the speed of light by

$${v}_{p} = \frac{c}{n} .$$

where c is the speed of light and n is the index of refraction of the material.

Thus, for the phase velocity to travel faster than the speed of light and thereby extinguish phase delay, the effective index of refraction must be less than one, i.e., 0<n<1 (for a cloak embedded in free space). A central advantage of the metal lens approach is that large scale objects can be cloaked due to the low-loss nature of the metal lens.

Cloaking barrier sheath 30 substantially reduces the EM signature of transmitter conduit 20, thus substantially minimizing the effect of the cloaked field sensor apparatus 100 on an EM field.

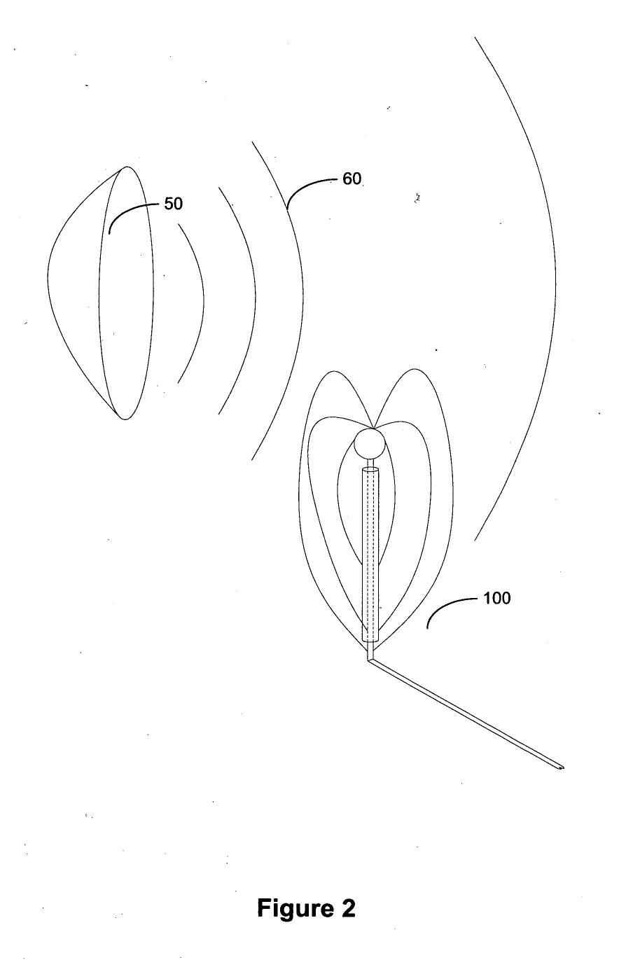

FIG. 2 illustrates an exemplary embodiment of cloaked field sensor apparatus 100 in use with an EM field source 50 emitting EM field 60. Cloaked field sensor apparatus 100 is present in the EM field 60. Cloaking barrier sheath 30 substantially reduces the signature of cloaked field sensor apparatus 100, thereby substantially minimizing the influence of the cloaked field sensor apparatus 100 on EM field 60. In the exemplary embodiment shown, the EM field 60 has characteristics of both electric fields and magnetic fields.

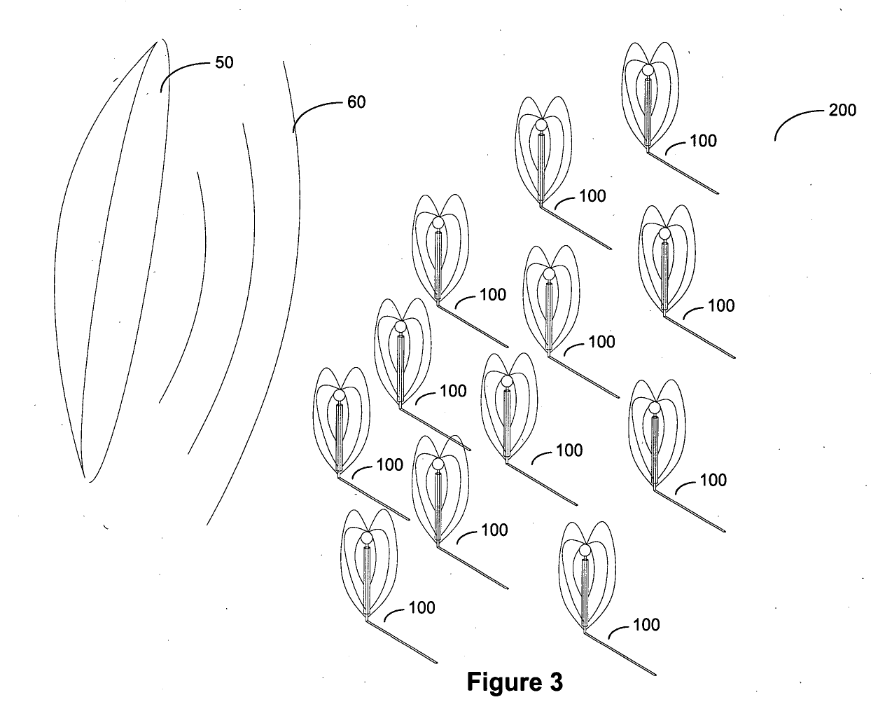

FIG. 3 illustrates an exemplary embodiment of mulitple cloaked field sensor apparatuses 100 arranged to form field sensor array 200 in an EM field 60, which is generated by the EM field source 50, such as a radar transmitter or waveguide. Field sensor array 200 has a substantially minimal impact on EM field 60 as a result of the cloaking barrier sheath 30 on each cloaked field sensor apparatus 100.

As illustrated in FIG. 3, each transmitter conduit 20 contains an identical cloaked barrier sheath 30. In further exemplary embodiments, transmitter conduits 20 used with field sensor array 200 may be of different materials or designs.

While certain features of the embodiments of the invention have been illustrated as described herein, many modifications, substitutions, changes and equivalents will now occur to those skilled in the art. It is, therefore, to be understood that the appended claims are intended to cover all such modifications and changes as fall within the true spirit of the embodiments.

What is claimed is:

1. An electromagnetic sensory apparatus for measuring a characteristic of an ambient electromagnetic field and communicating with a receiver, said apparatus comprising:
a field sensor probe for measuring the characteristic as an output;
a transmitter conduit communicating with said field sensor probe to transmit said output to the receiver, wherein said transmitter conduit has a surface located in the electromagnetic field;
a cloaking barrier sheath that substantially surrounds said surface of said transmitter conduit;
wherein said cloaking barrier sheath interacts with the electromagnetic field to form an electromagnetic cloaking interface.

2. The apparatus of claim 1, wherein said transmitter conduit is selected from at least one of an electric wire, an electric cable, a waveguide and a fiber optic cable.

3. The apparatus of claim 1, wherein said cloaking barrier sheath is selected at least one of a mantle cloak, metamaterial, plasmonic material, scattering-reduction material, and a metal lens.

4. The apparatus of claim 1, wherein said cloaking barrier sheath has one of a metallic surface and metallic bulk, either of which having a periodic pattern.

5. The apparatus of claim 4, wherein said periodic pattern is smaller than a wavelength of the electromagnetic field.

6. The apparatus of claim 1, wherein said cloaking barrier sheath is composed of a plasmonic material having low positive dielectric permittivity.

7. A cloaked electromagnetic field sensor system for measuring a characteristic of an ambient electromagnetic field, said system comprising:
a field transmitter that produces an ambient electromagnetic field;
a plurality of field sensor probes located in said electromagnetic field, each probe measuring the characteristic as an output;
a transmitter conduit communicating with said plurality of field sensor probes to transmit said output from each of said plurality of field sensor probes, said transmitter conduit having a surface disposed within said electromagnetic field;
a cloaking barrier sheath that substantially surrounds said surface of said transmitter conduit; and
a located receiver communicating with said transmitter conduit and configured to receive said output from said plurality of field sensor probes,
wherein said cloaking barrier sheath interacts with said electromagnetic field to form an electromagnetic cloaking interface.

8. The system of claim 7, wherein said transmitter conduit is selected from at least one of an electric wire, an electric cable, a waveguide and a fiber optic cable.

9. The system of claim 7, wherein said cloaking barrier sheath is selected from at least one of a mantle cloak, metamaterial, plasmonic material, scattering-reduction material, and a metal lens.

10. The system of claim 7, wherein said cloaking barrier sheath is composed of a plasmonic material having low positive dielectric permittivity.

11. The system of claim 7, wherein said at least one cloaking barrier sheath has a metallic surface with a periodic pattern.

12. The system of claim 11, wherein said periodic pattern is smaller than a wavelength of the electromagnetic field.

13. The system of claim 7, which includes a plurality of transmitter conduits having a corresponding plurality of cloaking barrier sheaths, wherein each of said transmitter conduits communicates with a corresponding probe of said plurality of field sensor probes.

14. The system of claim 13, wherein each of said cloaking barrier sheaths is identical.

15. The system of claim 13, wherein one of said cloaking barrier sheaths is distinct from a remainder of said cloaking barrier sheaths.

16. The system of claim 7, wherein said electromagnetic field is created by a radar emitter.

17. A method of minimizing the interference of an electromagnetic field sensor while measuring an electromagnetic field, said method comprising the steps of:
selecting an electromagnetic field to be measured;
selecting a cloaking barrier sheath that substantially minimizes interference with said electromagnetic field;
applying said cloaking barrier sheath to a surface of a transmitter conduit to be exposed in said electromagnetic field; and
operatively coupling said transmitter conduit to a field sensor probe to create a cloaked electromagnetic field sensor apparatus.

18. The method of claim 17 which further includes the step of creating a plurality of cloaked electromagnetic field sensor apparatuses, and aligning said plurality of cloaked electromagnetic field sensor apparatuses to form a cloaked field sensor array.

19. The method of claim 17 wherein each of said cloaked electromagnetic field sensor apparatuses has at least one of said cloaking barrier sheaths that is distinct from a remainder of said cloaking barrier sheaths.
